(19) United States
(12) Patent Application Publication
(10) Pub. No.: US 2024/0194632 A1
(43) Pub. Date: Jun. 13, 2024

(54) WIRE COATING APPARATUS

(71) Applicants: Woong Chul SHIN, Daejeon (KR); Min BAEK, Daejeon (KR)

(72) Inventors: Woong Chul SHIN, Daejeon (KR); Min BAEK, Daejeon (KR)

(21) Appl. No.: 18/555,282

(22) PCT Filed: Feb. 24, 2022
(86) PCT No.: PCT/KR2022/002733

§ 371 Date: Oct. 13, 2023

(30) Foreign Application Priority Data
Feb. 26, 2021 (KR) 10-2021-0026145

(51) Int. Cl. H01L 23/00; B65H 59/10; C23C 16/40; C23C 16/455; C23C 16/458; C23C 16/54

(52) U.S. Cl. CPC H01L 24/745; B65H 59/10; C23C 16/402; C23C 16/403; C23C 16/405; C23C 16/45544; C23C 16/458; C23C 16/545; B65H 2701/361; H01L 24/45; H01L 2224/45124; H01L 2224/45139; H01L 2224/45144; H01L 2224/45147; H01L 2224/45686; H01L 2224/745; H01L 2924/05341; H01L 2924/05432; H01L 2924/05442

(57) ABSTRACT

The present invention relates to a wire coating apparatus capable of evenly coating an insulating thin film on the surface of a wire such as a bonding wire having a small diameter, and the wire insulating thin film coating apparatus according to the present invention comprises: a coating portion which coats the surface of the wire with the insulating thin film while being blocked from the outside; and a wire process setting portion which is installed to be movable to the inside and outside of the coating portion and on which the wire is wound while the inside and outside of the wire are exposed so that a coating process of the insulating thin film is performed in the coating portion.

### TECHNICAL FIELD

The present disclosure relates to a wire coating apparatus, and more specifically, to a wire coating apparatus capable of evenly coating an insulating thin film on the surface of a wire such as a bonding wire having a small diameter.

### BACKGROUND ART

In a package process which electrically connects an electrode of a semiconductor device and a lead frame of a mounting substrate, a bonding wire is used. Conventionally, gold, which has excellent electrical conductivity, thermal conductivity, and chemical resistance, has been used for such bonding wires.

However, since gold is a precious metal and is expensive, the manufacturing unit price of semiconductor packages increases. Therefore, research on bonding wires that use inexpensive raw materials (such as silver, copper, and the like) as an alternative for the conventional gold-based bonding wires is ongoing.

To replace the bonding wires made of gold, there is ongoing development of copper (Cu) bonding wires which have excellent electrical conductivity. However, since the surface of the copper bonding wire is easily oxidized when exposed to the air, the copper bonding wire has a problem in adhesion properties. Additionally, as the degree of integration of semiconductor devices increases, the distance between neighboring bonding wires becomes shorter, and it leads to a short circuit due to touching between the bonding wires.

To overcome the problems, techniques which forms palladium on the outer surface of the copper bonding wire or coats the outer surface of the copper bonding wire with a polymer have been proposed. However, when palladium is formed, electrical resistance of palladium is more than six times higher than that of copper, and polymer coating is deteriorated in bonding characteristics and adhesion properties during wire bonding.

Therefore, there is an urgent need for the development of a technique capable of forming an insulating film, which can prevent the oxidation of copper and still have excellent insulating properties, on the surface of the bonding wire.

### DISCLOSURE

### Technical Problem

Accordingly, the present invention has been made in view of the above-mentioned problems occurring in the related art, and it is an object of the present invention to provide a wire coating apparatus which can evenly coat an insulating film on the surface of a wire such as a bonding wire having a small diameter.

### Technical Solution

To accomplish the above-mentioned objects, according to the present invention, there is provided a wire coating apparatus including: a coating unit for coating an insulating film on the surface of a wire in a state isolated from the outside; and a wire process setting unit which is movable between the inside and the outside of the coating unit and performs an insulating film coating process inside the coating unit when the wire is wound in such a way that the inside and the outside of the wire are exposed.

Moreover, in the present invention, the wire process setting unit includes: a central part which is formed in a pillar shape at the center; and a plurality of wire contact parts which are formed on the outer face of the central part to be spaced apart from one another, and have linear contact ends to allow the wire to be point-contacted when wound.

Furthermore, in the present invention, the plurality of wire contact parts are installed radially around the central part to be spaced at a predetermined angular interval.

Additionally, in the present invention, each wire contact part is formed in a long bar shape.

In addition, in the present invention, each wire contact part is formed in a plate shape.

Moreover, in the present invention, the wire insulating film coating apparatus further includes: a wire loading unit which is installed outside the coating unit, and winds the wire on the wire setting unit in such a way that the wire does not come in contact with each other in a length direction.

Furthermore, in the present invention, the wire loading unit includes: a wire supply roll on which a predetermined amount of the wire is wound; a rotating part which rotates the wire process setting unit to transfer the wire from the wire supply roll to the wire process setting unit in a processing state; a wire unwinding part which changes the relative position of the wire being wound on the wire process setting unit in the length direction of the wire process setting unit between the wire supply roll and the wire process setting unit, such that the wire is wound without contact in the length direction; and a tension adjusting part which is installed on the wire unwinding part to consistently adjust the tension of the wire wound on the wire process setting unit.

Additionally, in the present invention, the wire unwinding part is a moving bearing which changes the position of the wire wound on the wire process setting part while moving in the length direction of the wire process setting unit.

In addition, in the present invention, the wire unwinding part includes: a bearing which transfers the wire from a fixed position to the wire process setting unit; and a setting unit moving means which changes the winding position of the wire while moving the wire process setting unit relative to the bearing.

Moreover, in the present invention, the wire is made of one of copper (Cu), gold (Au), silver (Ag), and aluminum (Al).

Furthermore, in the present invention, the wire is a bonding wire.

Additionally, in the present invention, the wire is wound on the wire contact part with an interval of 10 mm or less from the neighboring wire.

In addition, in the present invention, the wire is wound on the wire contact part with an interval of 0.5 mm or less from the neighboring wire.

Moreover, in the present invention, the insulating film is coated with a thickness of 1 to 100 nm

Furthermore, in the present invention, the insulating film includes at least one of Al2O3, TiO2, and SiO2.

In addition, in the present invention, the coating unit is an atomic layer deposition apparatus.

### Advantageous Effect

The wire insulating film coating apparatus according to the present invention can evenly coat an insulating film over the entire surface of a small-diameter wire, such as a bonding wire, which is set in large quantities.

### DESCRIPTION OF DRAWINGS

FIG. 1 is a conceptual diagram illustrating a wire insulating film coating apparatus according to an embodiment of the present invention.

FIG. 2 is a perspective view illustrating a structure of a wire process setting unit according to an embodiment of the present invention.

FIG. 3 is a perspective view illustrating a structure of a wire process setting unit according to another embodiment of the present invention.

FIG. 4 is a perspective view illustrating a structure of a wire process setting unit according to a further embodiment of the present invention.

FIG. 5 is a side view illustrating the structure of the wire process setting unit according to an embodiment of the present invention.

FIG. 6 is a conceptual diagram illustrating a wire insulating film coating apparatus according to another embodiment of the present invention.

FIG. 7 is a sectional view illustrating a structure of a wire according to an embodiment of the present invention.

FIG. 8 is a view illustrating a wound state of the wire according to an embodiment of the present invention.

FIG. 9 is a view illustrating a wound state of a wire according to another embodiment of the present invention.

### BEST MODE

Hereinafter, specific embodiments of the present invention will be described in detail with reference to the attached drawings.

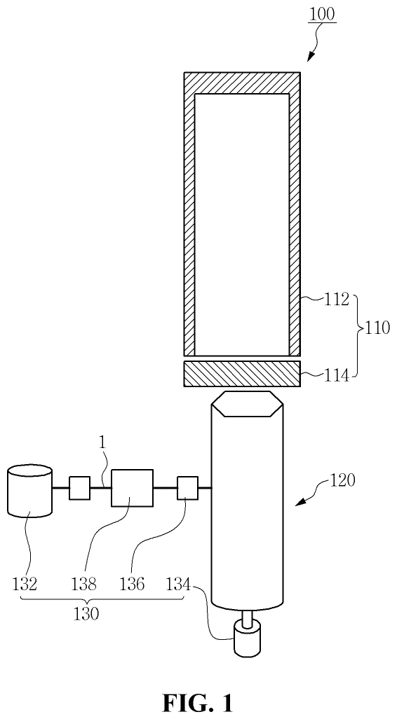

The wire insulating film coating apparatus according to an embodiment of the present invention, as illustrated in FIG. 1, includes a coating unit 110 and a wire process setting unit 120. First, the coating unit 110 is a component for coating an insulating film 2 on the surface of a wire 1 in a state isolated from the outside. That is, the coating unit 110 evenly coats the insulating film 2 over the entire surface of the wire 1 of a predetermined length wound on the wire process setting unit 120.

In the present embodiment, the coating unit 110 may be an atomic layer deposition apparatus or a chemical vapor deposition apparatus. The structure of the coating unit 110 will be described in brief. As illustrated in FIG. 1, the coating unit 110 includes a coating chamber 112, and a gate valve 114 installed in the coating chamber 112 to control an opening of the coating chamber.

Here, various components, such as a gas supply unit for coating an insulating film 2 and a gas exhaust unit, are installed in the coating chamber 112. The gate valve 114 controls the opening of the coating chamber 112 for the entry and exit of the wire process setting unit 120.

Next, the wire process setting unit 120 is a component which sets the wire 1 inside the coating unit 110 to perform a coating process of the insulating film 2 on the wire surface. Therefore, in the present embodiment, as illustrated in FIG. 1, the wire process setting unit 120 is installed to be movable inside and outside the coating unit 110, and has a structure in which the wire 1 is wound in a state in which the inside and the outside of the wire 1 are exposed to perform an insulating film coating process inside the coating unit 110.

Here, the expression, ‘the wire 1 is wound in a state in which the inside and the outside of the wire 1 are exposed’, means that, when the wire 1 with a predetermined length is wound around the wire process setting unit 120 multiple times such that not only the surface of the wire wound in the outward direction of the wire process setting unit are exposed. When the wire is wound on the wire process setting unit 120 in the state in which the inside and the outside of the wire are all exposed, an insulating film can be covered on the entire exposed surface of the wire. Of course, the insulating film may not be coated on some portions of the wire surface that come into contact with the wire process setting unit 120.

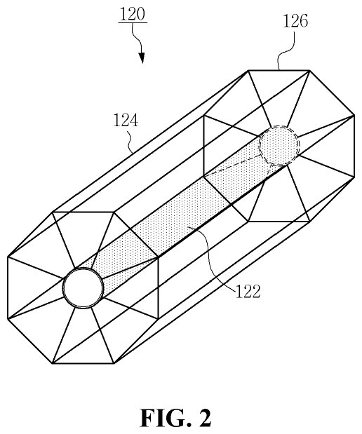

In the present embodiment, as illustrated in FIG. 2, the wire process setting unit 120 may include a central part 122 and a plurality of wire contact parts 124. First, the central part 122 is formed in a cylindrical or polygonal shape at the center, and provides a space and a structure for installing the wire contact part 124.

Next, the plurality of wire contact parts 124, as illustrated in FIG. 2, are formed on the outer face of the central part 122 to be spaced apart from one another, and have linear contact ends to allow the wire 1 to be point-contacted when wound. That is, the contact end of each wire contact part 124, with which the wire comes into outward contact with the wire contact part 124, is formed not in a planar shape but in a linear shape, so as to achieve not a line contact or a plane contact but a point contact with the wire wound on the outer surface thereof.

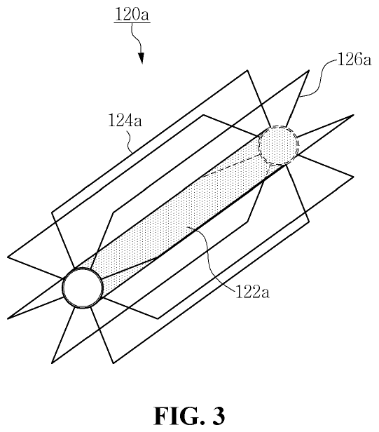

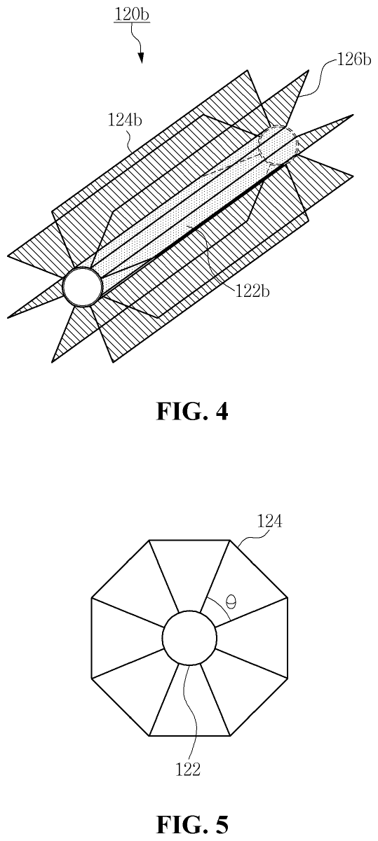

Therefore, the wire contact parts 124 and 124a can have a long bar shape as illustrated in FIGS. 2 and 3 or a plate shape as illustrated in FIG. 4. In a case in which the wire contact parts 124 and 124a are formed in the long bar shape, as illustrated in FIGS. 2 and 3, connection parts 126 and 126a which connect the wire contact parts 124 and 124a to the central part 122 and 122a are further included.

Meanwhile, in the present embodiment, as illustrated in FIG. 5, preferably, the plurality of wire contact parts 124 are installed radially around the central part 120 to be spaced at a predetermined angular interval (θ), thereby maintaining uniform tension in all sections of the wound wire.

Additionally, preferably, the contact end of the wire contact part 124 that is in contact with the wire has a smooth curved shape to prevent damage and cutting of the wound wire.

Moreover, The insulating film coating apparatus 100 according to the present embodiment, as illustrated in FIG. 1, may further include a wire loading unit 130. The wire must be loaded on the wire process setting unit 120 to be suitable for the insulating film coating process, and the wire loading unit 130 performs the wire loading process for the wire process setting unit 120.

That is, the wire loading unit 130 is installed outside the coating unit 110 as illustrated in FIG. 1, and loads the wire 1 onto the wire process setting unit 120 in a manner suitable for the insulating film coating process, namely, winds the wire on the wire setting unit 120 in such a way that the wire does not come in contact with each other in a length direction.

Here, the expression, ‘wind the wire on the wire setting unit 120 in such a way that the wire does not come in contact with each other in a length direction’ means that the wire 1 wound on one wire process setting unit 120, as illustrated in FIGS. 8 and 9, can meet the wires of different layers in a crossed state, but does not meet the wires of the same layer and is wound in parallel with the wires of the same layer to be spaced apart at predetermined intervals.

In the present embodiment, preferably, the wire 1 is wound on the wire contact part 124 with an interval of 10 mm or less from the neighboring wire, and more preferably, the wire is wound on the wire contact part with an interval of 0.5 mm or less from the neighboring wire.

In the present embodiment, as illustrated in FIG. 1, the wire loading unit 130 includes a wire supply roll 132, a rotating part 134, a wire unwinding part 136, and a tension adjusting part 138.

First, a predetermined amount of the wire is wound on the wire supply roll 132, and the wire is continuously supplied in the direction of the wire process setting unit 120. Therefore, the wire supply roll 132 is a roller with predetermined amount of the wire wound thereon, and can be installed as supplied by a wire supplier.

Next, the rotating part 134 rotates the wire process setting unit 120 and transfers the wire 1 from the wire supply roll 132 to the wire process setting unit 120 in a processing state. That is, the rotating part 134 is installed adjacent to the wire supply roll 132, and when the empty wire process setting unit 120 is combined, rotates the wire process setting unit 120. While the wire process setting unit 120 rotates by the rotating part, the wire is wound and loaded on the outer surface of the wire process setting unit.

Next, the wire unwinding part 136 changes the relative position of the wire being wound on the wire process setting unit 120 in the length direction of the wire process setting unit between the wire supply roll 132 and the wire process setting unit 120, such that the wire is wound without contact in the length direction.

If the rotating part 134 rotates the wire process setting unit 120 to wind the wire on the outer surface of the wire process setting unit such that the wire is repeatedly wound on the same position of the wire process setting unit 120, the wire and the neighboring wire come into contact with each other in the length direction. Accordingly, the entire surface of the wire cannot be coated with the insulating film. Therefore, during the wire winding process, the wire unwinding part 136 moves the wire process setting unit 120 in the length direction or moves the wire such that the positions of the wires which are wound on the wire process setting unit do not overlap and are spaced at a certain interval.

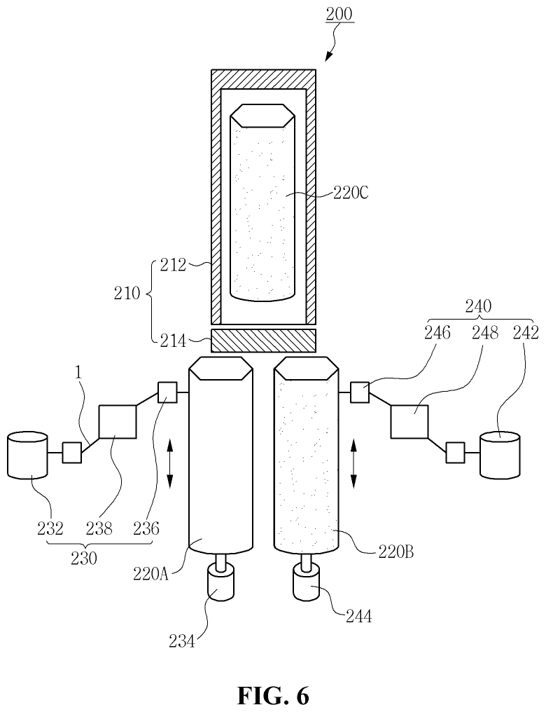

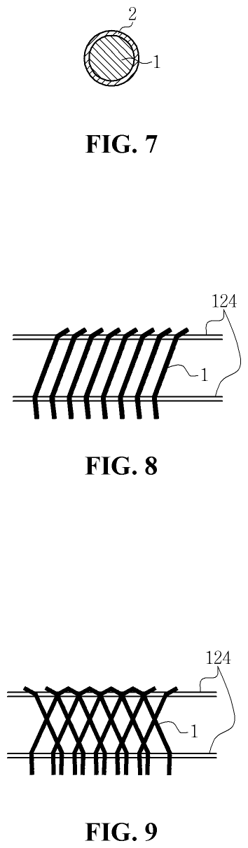

For this purpose, in the present embodiment, as illustrated in FIG. 6, the wire unwinding part may be a moving bearing 236 which changes the position of the wire wound on the wire process setting part while moving in the length direction of the wire process setting unit.

Furthermore, as illustrated in FIG. 1, the wire unwinding part 136 may include a bearing 136 which transfers the wire from a fixed position to the wire process setting unit, and a setting unit moving means (not illustrated) which changes the winding position of the wire while moving the wire process setting unit 120 relative to the bearing 136. In this case, the setting unit moving means can be installed internally in the rotating part 134.

Next, the tension adjusting part 138 is installed on the wire unwinding part to consistently adjust the tension of the wire wound on the wire process setting unit 120. That is, the tension adjusting part 138 pulls the wire, which is unwound from the wire supply roll 132 and wound on the wire process setting unit 120, with a consistent tension, and adjusts the wire to maintain a constant tension in the state in which the wire is wound on the wire process setting unit.

Although the above description has described setting the wire while transferring the wire from the wire loading unit 130 to the wire process setting unit 120, after the insulating film forming process is completed, the wire can be transferred and wound from the wire process setting unit 120 to the wire supply roll 132. In this case, the process is carried out while the wire is moved in the opposite direction of the wire process setting process.

### MODE FOR INVENTION

Meanwhile, as illustrated in FIG. 6, the wire insulating film coating apparatus according to the present embodiment may further include a wire unloading unit 240 which winds the wire 1, which was wound on the wire process setting unit 220b that the process was completed, onto a discharge spool 242 to discharge the wire. In this case, the wire unloading unit 240 can be applied in a case in which the discharge spool 242 has a different structure or specification from the supply roll 232, thereby increasing the process speed.

Additionally, in the present embodiment, it is desirable for the wire 1 to be made of one selected from copper (Cu), gold (Au), silver (Ag), and aluminum (Al), and specifically, it is preferable that the wire is a bonding wire.

In addition, in the present embodiment, it is desirable for the insulating film to be coated with a thickness of 1 to 100 nm, and preferably, the insulating film includes at least one of Al2O3, TiO2, and SiO2.

### INDUSTRIAL APPLICABILITY

The wire coating apparatus according to the present invention is essential technology for the semiconductor industry, as the wire coating apparatus is equipment capable of rapidly mass-producing a groundbreaking new structure of a bonding wire, which is absolutely necessary in the field of semiconductor manufacturing.

1. A wire insulating film coating apparatus comprising:
a coating unit for coating an insulating film on the surface of a wire in a state isolated from the outside; and
a wire process setting unit which is movable between the inside and the outside of the coating unit and performs an insulating film coating process inside the coating unit when the wire is wound in such a way that the inside and the outside of the wire are exposed.

2. The wire insulating film coating apparatus according to claim 1, wherein the wire process setting unit comprises:
a central part which is formed in a pillar shape at the center; and
a plurality of wire contact parts which are formed on the outer face of the central part to be spaced apart from one another, and have linear contact ends to allow the wire to be point-contacted when wound.

3. The wire insulating film coating apparatus according to claim 2, wherein the plurality of wire contact parts are installed radially around the central part to be spaced at a predetermined angular interval.

4. The wire insulating film coating apparatus according to claim 2, wherein each wire contact part is formed in a long bar shape.

5. The wire insulating film coating apparatus according to claim 2, wherein each wire contact part is formed in a plate shape.

6. The wire insulating film coating apparatus according to claim 1, further comprising:
a wire loading unit which is installed outside the coating unit, and winds the wire on the wire setting unit in such a way that the wire does not come in contact with each other in a length direction.

7. The wire insulating film coating apparatus according to claim 6, wherein the wire loading unit comprises:
a wire supply roll on which a predetermined amount of the wire is wound;
a rotating part which rotates the wire process setting unit to transfer the wire from the wire supply roll to the wire process setting unit in a processing state;
a wire unwinding part which changes the relative position of the wire being wound on the wire process setting unit in the length direction of the wire process setting unit between the wire supply roll and the wire process setting unit, such that the wire is wound without contact in the length direction; and
a tension adjusting part which is installed on the wire unwinding part to consistently adjust the tension of the wire wound on the wire process setting unit.

8. The wire insulating film coating apparatus according to claim 7, wherein the wire unwinding part is a moving bearing which changes the position of the wire wound on the wire process setting part while moving in the length direction of the wire process setting unit.

9. The wire insulating film coating apparatus according to claim 7, wherein the wire unwinding part comprises:
a bearing which transfers the wire from a fixed position to the wire process setting unit; and
a setting unit moving means which changes the winding position of the wire while moving the wire process setting unit relative to the bearing.

10. The wire insulating film coating apparatus according to claim 1, wherein the wire is made of one of copper (Cu), gold (Au), silver (Ag), and aluminum (Al).

11. The wire insulating film coating apparatus according to claim 1, wherein the wire is a bonding wire.

12. The wire insulating film coating apparatus according to claim 2, wherein the wire is wound on the wire contact part with an interval of 10 mm or less from the neighboring wire.

13. The wire insulating film coating apparatus according to claim 12, wherein the wire is wound on the wire contact part with an interval of 0.5 mm or less from the neighboring wire.

14. The wire insulating film coating apparatus according to claim 1, wherein the insulating film is coated with a thickness of 1 to 100 nm

15. The wire insulating film coating apparatus according to claim 1, wherein the insulating film includes at least one of Al2O3, TiO2, and SiO2.

16. The wire insulating film coating apparatus according to claim 1, wherein the coating unit is an atomic layer deposition apparatus.
